(19) United States
(12) Patent Application Publication
(10) Pub. No.: US 2024/0030343 A1
(43) Pub. Date: Jan. 25, 2024

(54) TRANSISTOR STRUCTURE WITH HYBRID GATE DIELECTRIC STRUCTURE AND ASYMMETRIC SOURCE/DRAIN REGIONS

(71) Applicant: GlobalFoundries U.S. Inc., Malta, NY (US)

(72) Inventors: Saloni Chaurasia, Leander, TX (US); Man Gu, Malta, NY (US); Jagar Singh, Clifton Park, NY (US)

(21) Appl. No.: 17/814,611

(22) Filed: Jul. 25, 2022

(51) Int. Cl. H01L 29/78; H01L 29/08; H01L 29/51

(52) U.S. Cl. CPC H01L 29/7835; H01L 29/0847; H01L 29/517

(57) ABSTRACT

A transistor structure includes a semiconductor substrate with a source region and a drain region therein that are asymmetric. A gate dielectric structure includes a first gate oxide region over a portion of the source region, a second gate oxide region over a portion of the drain region, and a high dielectric constant (high-K) dielectric layer contacting the semiconductor substrate and separating the first gate oxide region from the second gate oxide region. A gate body is over the gate dielectric structure.

### BACKGROUND

The present disclosure relates to a semiconductor device, and more particularly, to a transistor structure using a hybrid gate dielectric structure and asymmetric source/drain regions.

Transistor structures for radio frequency (RF) applications have performance and reliability limited by a low cut-off frequency (Ft) and maximum oscillation frequency (Fmax) and a low breakdown voltage.

### SUMMARY

All aspects, examples and features mentioned below can be combined in any technically possible way.

An aspect of the disclosure provides a transistor structure comprising: a semiconductor substrate; a source region in the semiconductor substrate; a drain region in the semiconductor substrate, wherein the source region and the drain region are asymmetric; a gate dielectric structure including a first gate oxide region over a portion of the source region, a second gate oxide region over a portion of the drain region, and a high dielectric constant (high-K) dielectric layer contacting the semiconductor substrate and separating the first gate oxide region from the second gate oxide region; and a gate body over the gate dielectric structure.

Another aspect of the disclosure includes any of the preceding aspects, and the source region and the drain region include asymmetric graded source/drain regions.

Another aspect of the disclosure includes any of the preceding aspects, and the source region is surrounded by a first doping well within the semiconductor substrate and the drain region is surrounded by a second, different doping well within the semiconductor substrate, and wherein the first gate oxide region is over the first doping well and the second gate oxide region is over the second, different doping well.

Another aspect of the disclosure includes any of the preceding aspects, and further comprising a well gap in the semiconductor substrate between the first doping well and the second, different doping well, wherein the first gate oxide region and the second gate oxide region are not over the well gap.

Another aspect of the disclosure includes any of the preceding aspects, and the high-K dielectric layer extends only between sidewalls of the first gate oxide region and the second gate oxide region.

Another aspect of the disclosure includes any of the preceding aspects, and the high-K dielectric layer extends between sidewalls of the first gate oxide region and the second gate oxide region and over an upper surface of both the first gate oxide region and the second gate oxide region.

Another aspect of the disclosure includes any of the preceding aspects, and the first gate oxide region and the second gate oxide region are thicker than the high-K dielectric layer.

Another aspect of the disclosure includes any of the preceding aspects, and the semiconductor substrate includes a semiconductor fin.

Another aspect of the disclosure includes any of the preceding aspects, and the first and second doping wells are devoid of a trench isolation therein.

Another aspect of the disclosure includes any of the preceding aspects, and the second gate oxide region over the portion of the drain region is laterally longer than the first gate oxide region over the portion of the source region.

Another aspect of the disclosure includes any of the preceding aspects, and the gate body includes a single work function metal layer having a uniform thickness over the source region and the drain region.

An aspect of the disclosure includes a transistor structure comprising: a semiconductor fin; a source region in the semiconductor fin; a drain region in the semiconductor fin, wherein the source region and the drain region are asymmetric; a gate dielectric structure including a first gate oxide region over a portion of the source region, a second gate oxide region over a portion of the drain region, and a high dielectric constant (high-K) dielectric layer contacting the semiconductor fin and separating the first gate oxide region from the second gate oxide region; a first doping well extending under the semiconductor fin and surrounding the source region; a second, different doping well extending under the semiconductor fin and surrounding the drain region, wherein the first gate oxide region is over the first doping well and the second gate oxide region is over the second, different doping well, and wherein the first and second doping wells are devoid of a trench isolation therein; and a gate body over the gate dielectric structure.

Another aspect of the disclosure includes any of the preceding aspects, and further comprising a well gap in the semiconductor fin between the first doping well and the second, different doping well, wherein the first gate oxide region and the second gate oxide region are not over the well gap.

Another aspect of the disclosure includes any of the preceding aspects, and the high-K dielectric layer extends only between sidewalls of the first gate oxide region and the second gate oxide region.

Another aspect of the disclosure includes any of the preceding aspects, and the high-K dielectric layer extends between sidewalls of the first gate oxide region and the second gate oxide region and over an upper surface of both the first gate oxide region and the second gate oxide region.

Another aspect of the disclosure includes any of the preceding aspects, and the second gate oxide region over the portion of the drain region is laterally longer than the first gate oxide region over the portion of the source region.

Another aspect of the disclosure includes any of the preceding aspects, and the gate body includes a single work function metal layer having a uniform thickness over the source region and the drain region.

An aspect of the disclosure includes a transistor structure comprising: a semiconductor fin; a source region in the semiconductor fin; a drain region in the semiconductor fin, wherein the source region and the drain region are asymmetric; a gate dielectric structure including a first gate oxide region over a portion of the source region, a second gate oxide region over a portion of the drain region, and a high dielectric constant (high-K) dielectric layer contacting the semiconductor fin and separating the first gate oxide region from the second gate oxide region, wherein the second gate oxide region over the portion of the drain region is laterally longer than the first gate oxide region over the portion of the source region; a first doping well extending under the semiconductor fin and surrounding the source region; a second, different doping well extending under the semiconductor fin and surrounding the drain region, wherein the first gate oxide region is over the first doping well and the second gate oxide region is over the second, different doping well, and wherein the first and second doping wells are devoid of a trench isolation therein; and a gate body over the gate dielectric structure, wherein the gate body includes a single work function metal layer having a uniform thickness over the source region and the drain region.

Another aspect of the disclosure includes any of the preceding aspects, and the high-K dielectric layer extends only between sidewalls of the first gate oxide region and the second gate oxide region.

Another aspect of the disclosure includes any of the preceding aspects, and the high-K dielectric layer extends between sidewalls of the first gate oxide region and the second gate oxide region and over an upper surface of both the first gate oxide region and the second gate oxide region.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a transistor structure, according to embodiments of the disclosure.

FIG. 2 shows a cross-sectional view of a transistor structure, according to other embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a transistor structure including a semiconductor substrate with a source region and a drain region therein that are asymmetric. A gate dielectric structure includes a first gate oxide region over a portion of the source region, a second gate oxide region over a portion of the drain region, and a high dielectric constant (high-K) dielectric layer contacting the semiconductor substrate and separating the first gate oxide region from the second gate oxide region. A gate body is over the gate dielectric structure. The transistor structure provides a smaller gate length and areal footprint by omitting a trench isolation in the drain region as is typically used in a laterally-diffused metal-oxide semiconductor (LDMOS) transistor structure in power RF applications. The asymmetric source/drain region provides about a 10% increase in Ft and Fmax (e.g., Ft>100 Gigahertz (GHz) and Fmax>200 GHz), and almost doubles the breakdown voltage, compared to conventional devices. The transistor structure can be used as a high voltage and high-performance RF power amplifier capable of frequencies of, for example, 6 GHz or higher, and with high current gain, low gate resistance (Rg), high transconductance (Gm), high intrinsic capacitance (Cgg), and low gate-source and gate-drain capacitances (Cgs, Cgd).

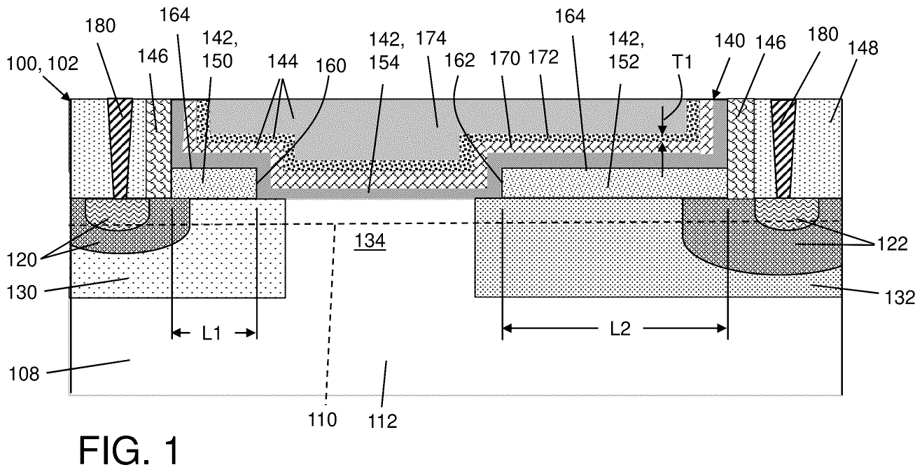

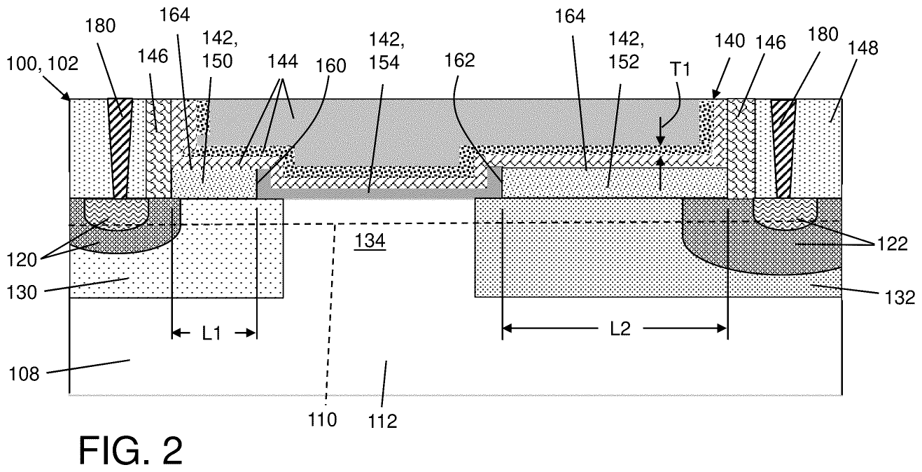

FIGS. 1 and 2 show cross-sectional views of a transistor structure 100 (hereafter “structure 100”) according to various embodiments of the disclosure. Structure 100 includes a semiconductor substrate 108. Semiconductor substrate 108 may include but is not limited to silicon, germanium, silicon germanium, silicon carbide, or any other common semiconductor material. Semiconductor substrate 108 may take the form of a bulk semiconductor substrate. In certain embodiments, semiconductor substrate 108 may include a semiconductor fin 110 (above dashed line) over a (bulk) semiconductor substrate 112. Semiconductor substrate 108 may include a dopant. In one embodiment, the dopant may include a p-type dopant, which may include but is not limited to: boron (B), indium (In) and gallium (Ga). P-type dopants are elements introduced to semiconductor to generate free holes by “accepting” electron from semiconductor atom and “releasing” the hole at the same time. The dopant may be introduced to semiconductor substrate 108 in any now known or later developed fashion, e.g., in-situ doping during formation, or ion implanting. Usually in doping, a dopant, a dosage, and an energy level are specified and/or a resulting doping level may be specified. A dosage may be specified in the number of atoms per square centimeter (cm²) and an energy level (specified in keV, kilo-electron-volts), resulting in a doping level (concentration in the substrate) of a number of atoms per cubic centimeter (cm³). An example of doping is implanting with B (boron) with a dosage of between about 1E12 and 1E13 atoms/cm², and an energy of about 40 to 80 keV to produce a dopant concentration of between 1E17 and 1E18 atoms/cm³.

Transistor structure 100 also includes a source region 120 in semiconductor substrate 108 and a drain region 122 in semiconductor substrate 108. Source region 120 and drain region 122 are asymmetric, meaning they have different widths and/or depths. Source region 120 and drain regions 122 may be formed using any now known or later developed semiconductor fabrication technique to form the asymmetry. For example, to form source region 120, an additional sacrificial spacer (not shown) may be formed about the gate region (e.g., in the form of dummy gate) and an area for drain region 122 may be masked, leaving an area for source region 120 exposed. A doping by, for example, ion implantation, followed by an anneal to drive in the dopants may then be performed. Subsequently, to form drain region 122, the drain mask may be removed, and source region 120 may be masked, leaving an area for drain region 122 exposed. A different doping by, for example, ion implantation followed by an anneal to drive in the dopants may be performed. The source mask and any sacrificial spacer may then be removed using conventional techniques.

Source/drain regions 120, 122 may be doped with an n-type dopant, but to different depths and/or widths, and/or dopant concentrations to make them asymmetric. In the example shown, drain region 122 is wider and deeper than source region 120. In one non-limiting example, drain region 122 may be approximately 10-100 nanometers wider and deeper than source region 120. (Note, the different shading for source region 120 and drain region 122 indicate the epitaxial areas (lighter) from the non-epitaxial areas of the regions). N-type dopants may include but are not limited to: phosphorous (P), arsenic (As), or antimony (Sb). N-type dopants more generally are elements introduced to semiconductor to generate free electrons by “donating” electrons to the semiconductor. In certain embodiments, source region 120 and drain region 122 are asymmetric graded source/drain regions 120, 122, meaning the dopant profile changes gradually along their depth into semiconductor substrate 108. The asymmetric graded source/drain regions 120, 122 provide higher breakdown voltage.

Source region 120 may be surrounded by a first doping well 130 extending under semiconductor substrate 108, e.g., fin 110, and drain region 122 may be surrounded by a second, different doping well 132 extending under semiconductor substrate 108. First doping well 130 may take the form of a p-type doped well (hereafter “p-well”) 130. The p-type dopant may be the same as semiconductor substrate 108, but with a higher dopant concentration. P-well 130 may be formed using any now known or later developed semiconductor fabrication technique, e.g., mask-directed ion implantation prior to formation of source region 120. Second doping well 132 may take the form of an n-type doped well (hereafter “n-well”) 132. The n-type dopant may be the same as source region 120 and drain region 122, but with a lower dopant concentration. N-well 132 may be formed using any now known or later developed semiconductor fabrication technique, e.g., mask-directed ion implantation prior to formation of drain region 122. Transistor structure 100 has p-well 130 and n-well 132 separated by a well gap 134 having the same doping as semiconductor substrate 108. Well gap 134 is in semiconductor substrate 108 between p-well 130 and n-well 132 such that the two wells 130, 132 do not interface. In contrast to laterally-diffused metal-oxide semiconductor (LDMOS) devices typically used for RF applications, n-well 132 is devoid of a trench isolation therein. The omission of trench isolations provides transistor structure 100 with a smaller areal footprint compared to devices that include the trench isolation.

Structure 100 may also include a gate 140 including a gate dielectric structure 142 and a gate body 144 thereover. A spacer 146 may surround gate 140 within an inter-layer dielectric 148. Spacer 146 may include any now known or later developed spacer material such as silicon nitride. ILD 148 may include any now known or later developed dielectric such as but not limited to silicon oxide, silicate glass (SG), silicon oxycarbide, or fluorine doped silicon oxide.

Gate dielectric structure 142 includes a first gate oxide region 150 over a portion of source region 120, a second gate oxide region 152 over a portion of drain region 122, and a high dielectric constant (“high-K”) dielectric layer 154 contacting semiconductor substrate 108 and separating first gate oxide region 150 from second gate oxide region 152. Since gate dielectric structure 142 includes both gate oxide regions 150, 152 and high-K dielectric layer 154 in contact with semiconductor substrate 108 (and not just a single gate oxide layer), it may be referred to as a ‘hybrid’ gate dielectric structure. First gate oxide region 150 and second gate oxide region 152 are thicker than high-K dielectric layer 154. In addition, second gate oxide region 152 over the portion of drain region 122 is laterally longer than first gate oxide region 150 over the portion of source region 120, i.e., L1<L2. Here, rather than a single extended gate (EG) thick gate oxide, the gate oxide is segmented into two gate oxide regions 150, 152 that are separated by high-K dielectric layer 154. First gate oxide region 150 is over p-well 130 and second gate oxide region 152 is over n-well 132. That is, the segmented gate oxide regions 150, 152 are on respective p-well 130 and n-well 132, which lowers parasitic capacitance (Cgs/Cgd) and provides higher gate capacitance (Cgg). The presence of well gap 134 between p-well 130 and n-well 132 with high-K dielectric layer 154 but without gate oxide thereover provides high transconductance (Gm) and higher breakdown voltage (Vbd).

Gate oxide regions 150, 152 may include any now known or later developed silicon oxide. High-K dielectric layer 154 may include any now known or later developed high-K material (i.e., K>3.9) typically used for metal gates such as but not limited to: metal oxides such as tantalum oxide (Ta₂O₅), barium titanium oxide (BaTiO₃), hafnium oxide (HfO₂), zirconium oxide (ZrO₂), aluminum oxide (Al₂O₃) or metal silicates such as hafnium silicate oxide (Hf_{A1}Si_{A2}O_{A3}) or hafnium silicate oxynitride (Hf_{A1}Si_{A2}O_{A3}N_{A4}), where A1, A2, A3, and A4 represent relative proportions, each greater than or equal to zero and A1+A2+A3+A4 (1 being the total relative mole quantity).

Gate dielectric structure 142 may be formed after ILD 148 fill about a dummy gate (not shown in position of gate 140), planarization and dummy gate removal (polysilicon pull, excepting the gate oxide layer). More particularly, gate oxide regions 150, 152 may be formed after ILD 148 fill and poly pull during a dummy gate process, which exposes the solid, single gate oxide layer at the bottom of the dummy gate. A patterned mask, perhaps with an additional oxide layer thereunder, may expose the space between the would-be first and second gate oxide regions 150, 152. An etching (e.g., a reactive ion etch (RIE) or other appropriate etching chemistry) may remove the exposed part of the oxide layer to form first and second gate oxide regions 150, 152. High-K dielectric layer 154 may be formed with the rest of gate 140, e.g., through deposition of the layers—described herein.

In the FIG. 1 embodiment, high-K dielectric layer 154 extends between sidewalls 160, 162 of first gate oxide region 150 and second gate oxide region 152 and over an upper surface 164 of both first gate oxide region 150 and second gate oxide region 152. In the FIG. 2 embodiment, high-K dielectric layer 154 extends only between sidewalls 160, 162 of first gate oxide region 150 and second gate oxide region 152, i.e., it is not over upper surface 164.

In addition to gate dielectric structure 142, gate body 144 of gate 140 may include layers of a metal gate. The metal gate may include, for example, a barrier layer 170, a work function metal (WFM) layer 172, and a gate conductor 174. Barrier layer 170 may include any now known or later developed refractory metal liner material such as titanium nitride. WFM layer 172 may include various metals depending on whether for an NFET or PFET device, but may include, for example: aluminum (Al), zinc (Zn), indium (In), copper (Cu), indium copper (InCu), tin (Sn), tantalum (Ta), tantalum nitride (TaN), tantalum carbide (TaC), titanium (Ti), titanium nitride (TiN), titanium carbide (TiC), TiAlC, TiAl, tungsten (W), tungsten nitride (WN), tungsten carbide (WC), polycrystalline silicon (poly-Si), and/or combinations thereof. Gate body 144 includes a single WFM layer 172 having a uniform thickness (T1). Gate conductor layer 174 may include any now known or later developed gate conductor such as tungsten (W). Each layer may be deposited using any appropriate deposition technique, e.g., atomic layer deposition (ALD), chemical vapor deposition (CVD), plasma-enhanced CVD (PECVD), etc. For the FIG. 2 embodiment, after high-K dielectric layer 154 deposition, a patterned mask may cover the layer between first and second gate oxide regions 150, 152 and an etching process (e.g., a RIE or other appropriate etching chemistry) may remove it from upper surfaces 164 of gate oxide regions 150, 152, resulting in high-K dielectric layer 154 as shown.

While only contacts 180 to source region 120 and drain region 122 are shown, it will be recognized that any necessary interconnect layers may be formed over transistor structure 100, as shown in FIGS. 1-2.

Embodiments of the disclosure provide various technical and commercial advantages, examples of which are discussed herein. The transistor structure provides a smaller areal footprint by omission of a trench isolation in the drain region as is typically used in LDMOS transistor structures in power RF applications. The transistor structure includes an asymmetric source/drain region that provides about a 10% increase in Ft and Fmax (e.g., Ft>100 Gigahertz (GHz) and Fmax>200 GHz), and almost doubles the breakdown voltage, compared to conventional devices. The transistor structure provides benefit as a high voltage and high-performance RF power amplifier that can be used at frequencies of, for example, 6 GHz and above. In addition, the transistor structure exhibits improved performance parameters such as: high current gain, low gate resistance (Rg), high transconductance (Gm), high intrinsic capacitance (Cgg), and low gate-source and gate-drain capacitances (Cgs, Cgd).

The structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor. The transistor structure can be applied in a fin-type field effect transistor (FinFET) setting.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A transistor structure comprising:
a semiconductor substrate;
a source region in the semiconductor substrate;
a drain region in the semiconductor substrate, wherein the source region and the drain region are asymmetric;
a gate dielectric structure including a first gate oxide region over a portion of the source region, a second gate oxide region over a portion of the drain region, and a high dielectric constant (high-K) dielectric layer contacting the semiconductor substrate and separating the first gate oxide region from the second gate oxide region; and
a gate body over the gate dielectric structure.

2. The transistor structure of claim 1, wherein the source region and the drain region include asymmetric graded source/drain regions.

3. The transistor structure of claim 1, wherein the source region is surrounded by a first doping well within the semiconductor substrate and the drain region is surrounded by a second, different doping well within the semiconductor substrate, and wherein the first gate oxide region is over the first doping well and the second gate oxide region is over the second, different doping well.

4. The transistor structure of claim 3, further comprising a well gap in the semiconductor substrate between the first doping well and the second, different doping well, wherein the first gate oxide region and the second gate oxide region are not over the well gap.

5. The transistor structure of claim 1, wherein the high-K dielectric layer extends only between sidewalls of the first gate oxide region and the second gate oxide region.

6. The transistor structure of claim 1, wherein the high-K dielectric layer extends between sidewalls of the first gate oxide region and the second gate oxide region and over an upper surface of both the first gate oxide region and the second gate oxide region.

7. The transistor structure of claim 1, wherein the first gate oxide region and the second gate oxide region are thicker than the high-K dielectric layer.

8. The transistor structure of claim 1, wherein the semiconductor substrate includes a semiconductor fin.

9. The transistor structure of claim 1, wherein the first and second doping wells are devoid of a trench isolation therein.

10. The transistor structure of claim 1, wherein the second gate oxide region over the portion of the drain region is laterally longer than the first gate oxide region over the portion of the source region.

11. The transistor structure of claim 1, wherein the gate body includes a single work function metal layer having a uniform thickness over the source region and the drain region.

12. A transistor structure comprising:
a semiconductor fin;
a source region in the semiconductor fin;
a drain region in the semiconductor fin, wherein the source region and the drain region are asymmetric;
a gate dielectric structure including a first gate oxide region over a portion of the source region, a second gate oxide region over a portion of the drain region, and a high dielectric constant (high-K) dielectric layer contacting the semiconductor fin and separating the first gate oxide region from the second gate oxide region;
a first doping well extending under the semiconductor fin and surrounding the source region;
a second, different doping well extending under the semiconductor fin and surrounding the drain region, wherein the first gate oxide region is over the first doping well and the second gate oxide region is over the second, different doping well, and wherein the first and second doping wells are devoid of a trench isolation therein; and
a gate body over the gate dielectric structure.

13. The transistor structure of claim 12, further comprising a well gap in the semiconductor fin between the first doping well and the second, different doping well, wherein the first gate oxide region and the second gate oxide region are not over the well gap.

14. The transistor structure of claim 12, wherein the high-K dielectric layer extends only between sidewalls of the first gate oxide region and the second gate oxide region.

15. The transistor structure of claim 12, wherein the high-K dielectric layer extends between sidewalls of the first gate oxide region and the second gate oxide region and over an upper surface of both the first gate oxide region and the second gate oxide region.

16. The transistor structure of claim 12, wherein the second gate oxide region over the portion of the drain region is laterally longer than the first gate oxide region over the portion of the source region.

17. The transistor structure of claim 12, wherein the gate body includes a single work function metal layer having a uniform thickness over the source region and the drain region.

18. A transistor structure comprising:
a semiconductor fin;
a source region in the semiconductor fin;
a drain region in the semiconductor fin, wherein the source region and the drain region are asymmetric;
a gate dielectric structure including a first gate oxide region over a portion of the source region, a second gate oxide region over a portion of the drain region, and a high dielectric constant (high-K) dielectric layer contacting the semiconductor fin and separating the first gate oxide region from the second gate oxide region, wherein the second gate oxide region over the portion of the drain region is laterally longer than the first gate oxide region over the portion of the source region;
a first doping well extending under the semiconductor fin and surrounding the source region;
a second, different doping well extending under the semiconductor fin and surrounding the drain region, wherein the first gate oxide region is over the first doping well and the second gate oxide region is over the second, different doping well, and wherein the first and second doping wells are devoid of a trench isolation therein; and
a gate body over the gate dielectric structure, wherein the gate body includes a single work function metal layer having a uniform thickness over the source region and the drain region.

19. The transistor structure of claim 18, wherein the high-K dielectric layer extends only between sidewalls of the first gate oxide region and the second gate oxide region.

20. The transistor structure of claim 18, wherein the high-K dielectric layer extends between sidewalls of the first gate oxide region and the second gate oxide region and over an upper surface of both the first gate oxide region and the second gate oxide region.
